(19) United States
(12) Patent Application Publication
(10) Pub. No.: US 2019/0348786 A1
(43) Pub. Date: Nov. 14, 2019

(54) ELECTRICAL CONTACT AND SOCKET FOR ELECTRIC COMPONENT

(71) Applicant: ENPLAS CORPORATION, Kawaguchi-shi, Saitama (JP)

(72) Inventor: Osamu HACHUDA, Kawaguchi-shi (JP)

(73) Assignee: ENPLAS CORPORATION, Kawaguchi-shi, Saitama (JP)

(21) Appl. No.: 16/470,755

(22) PCT Filed: Dec. 22, 2017
(86) PCT No.: PCT/JP2017/046159

§ 371 Date: Jun. 18, 2019

(30) Foreign Application Priority Data
Dec. 27, 2016 (JP) 2016-254011

(51) Int. Cl. H01R 13/187; H01R 13/11; G01R 31/04; G01R 31/26; G01R 1/073

(52) U.S. Cl. CPC H01R 13/187; H01R 13/113; G01R 1/073; G01R 31/26; G01R 31/045

(57) ABSTRACT

An electric contact configured to make a section between a first contact part and a second contact part extendable/contractible. A spring part has a wave-like shape by continuously forming wave-shaped parts alternately on one and the other sides of an axis L as a center for connecting the first contact part and the second contact part, and is formed into a cylindrical shape while having a projection of the wave-shaped part on one side confronting a recess between projections of the wave-shaped parts on the other side. The projection of the wave-shaped part on the one side enters into the recess between the wave-shaped parts on the other side to bring the projection on the one side into abutment on the projection adjacent to the recess upon contraction of the spring part to stop a contracting motion, and establish a conduction state between the projections abutted on each other.

### CROSS-REFERENCE TO RELATED APPLICATION

This application is a U.S. National Stage Application which claims the benefit under 35 U.S.C. § 371 of PCT International Patent Application No. PCT/JP2017/046159, filed, Dec. 22, 2017, which claims the foreign priority benefit under 35 U.S.C. § 119 of Japanese Patent Application No. 2016-254011, filed Dec. 27, 2016, the contents of which are incorporated herein by reference.

### TECHNICAL FIELD

The present invention relates to an electric contact to be electrically connected to an electric component such as a semiconductor device (hereinafter referred to as “IC package”), and a socket for electric component having the electric contact disposed therein.

### BACKGROUND ART

A contact pin disposed in an IC socket serving as the socket for electric component has been conventionally known as the electric contact of type as described above. The IC socket is configured to be disposed on a wiring board for accommodating the IC package to be inspected. Terminals of the IC package and electrodes of the wiring board are electrically connected to each other via the contact pins so that the test such as a continuity test is conducted.

A contact pin conventionally known as described above is formed by bending the member having plate-like end portions, and an intermediate portion with both plate-like and wave-shaped sections into an integrated structure of a contact part to be brought into contact with the wiring board, a contact part to be brought into contact with the IC package, and a spring part for urging those contact parts in a mutually separating directions (see, for example, Patent Literature 1).

### CITATION LIST

### Patent Literature

Patent Literature 1: Japanese Patent Laid-Open No. 2006-266869

### SUMMARY OF INVENTION

### Technical Problem

In the above-described Patent Literature 1, as a result of contracting the contact pin against the urging force of the spring part, the contact pin is contracted to the level in excess of the limit of the elastic deformation of the spring part. The resultant plastic deformation of the spring part may cause the risk of failure in restoration to the original state.

It is an object of the present invention to provide an electric contact (contact pin) with durability improved by preventing the plastic deformation of the spring part and a socket (IC socket) for electric component.

### Solution to Problem

In order to solve the above-described problem, the invention according to claim 1 provides an electric contact to be disposed between a first electric component and a second electric component to establish electric connection therebetween, which includes a first contact part to be in contact with the first electric component, a second contact part to be in contact with the second electric component, and a cylindrical spring part formed from a conductive material with a plate-like section and a wavy section. It is configured to make a section between the first contact part and the second contact part extendable/contractible via the spring part. The spring part has a wave-like shape by continuously forming wave-shaped parts alternately on one and the other sides of an axis as a center for connecting the first contact part and the second contact part, and is formed into a cylindrical shape while having a projection of the wave-shaped part on one side confronting a recess between the projections of the wave-shaped parts on the other side. The projection of the wave-shaped part on the one side enters into the recess between the wave-shaped parts on the other side to bring the projection on the one side into abutment on the projection adjacent to the recess of the wave-shaped part on the other side upon contraction of the spring part to stop a contracting motion, and establish a conduction state between the projections abutted on each other.

In the invention according to claim 2 in addition to the invention according to claim 1, a protrusion is provided on the projection in a direction orthogonal to the axis, and configured to enter into the recess.

The invention according to claim 3 provides a socket for electric component including a socket body which is to be disposed on a first electric component, and includes a storage part to accommodate a second electric component, and the electric contact according to claim 1 or 2, which is disposed in the socket body, and to be in contact with a terminal of the first electric component, and a terminal of the second electric component.

### Advantageous Effects of Invention

The invention according to claim 1 is configured to allow the projection of the wave-shaped part on the one side to enter into the recess between the wave-shaped parts on the other side. Upon contraction of the spring part, the projection on the one side abuts on the projection adjacent to the recess of the wave-shaped part on the other side, which stops the contraction movement, and establishes the conduction state between the projections abutted on each other. This makes it possible to prevent the plastic deformation of the spring part without exceeding the limit of the elastic deformation. As a result, durability of the electric contact may be improved.

The invention according to claim 2 is configured to have the projection provided with the protrusion formed in the direction orthogonal to the axis. As the protrusion is structured to enter into the recess, the protrusion securely enters into the recess, making it possible to prevent the elastic deformation in excess of the limit.

The invention according to claim 3 includes the electric contact according to claim 1 or 2. This makes it possible to provide the socket for electric component, which prevents the plastic deformation of the spring part of the electric contact without exceeding the limit of the elastic deformation.

### BRIEF DESCRIPTION OF DRAWINGS

FIG. 1 is a perspective view showing a socket body of an IC socket according to a first embodiment of the present invention.

FIG. 2 is an exploded perspective view of the socket body of the IC socket according to the first embodiment.

FIG. 3 is an exploded perspective view of the socket body of the IC socket according to the first embodiment when seen at a different angle from FIG. 2.

FIG. 4 is a front view of a contact module of the socket body of the IC socket according to the first embodiment.

FIG. 5 is a longitudinal sectional view of the contact module in the socket body of the IC socket according to the first embodiment.

FIG. 6 is a front view showing a contact pin provided for the IC socket according to the first embodiment.

FIG. 7 is a back view showing the contact pin provided for the IC socket according to the first embodiment.

FIG. 8 is a partially enlarged longitudinal sectional view of the contact pin provided for the IC socket according to the first embodiment as shown in FIG. 6.

FIG. 9 is a development view of the contact pin provided for the IC socket according to the first embodiment.

FIG. 10 is a front view showing a contact pin provided for an IC socket according to a second embodiment of the present invention.

FIG. 11 is a back view showing the contact pin provided for the IC socket according to the second embodiment.

FIG. 12 is a longitudinal sectional view of the contact pin provided for the IC socket according to the second embodiment.

FIG. 13 is a partially enlarged longitudinal sectional view of the contact pin provided for the IC socket according to the second embodiment as shown in FIG. 12.

FIG. 14 is a partially enlarged front view of the contact pin provided for the IC socket according to the second embodiment as shown in FIG. 10.

FIGS. 15A and 15B are development views of the contact pin provided for the IC socket according to the second embodiment.

### DESCRIPTION OF EMBODIMENTS

Embodiments of the present invention will be described.

### First Embodiment of the Invention

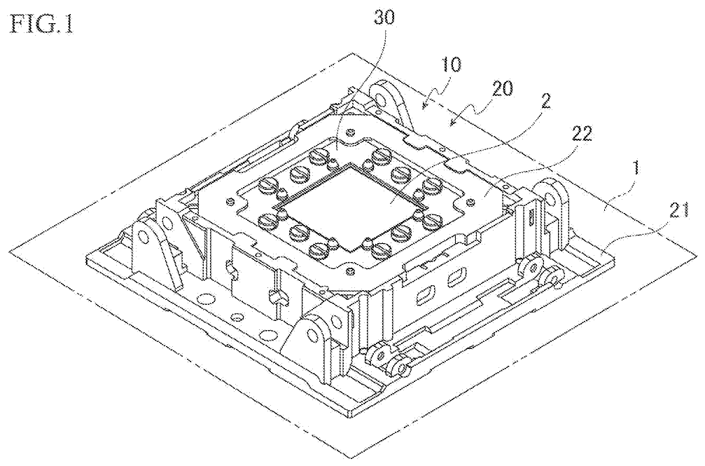

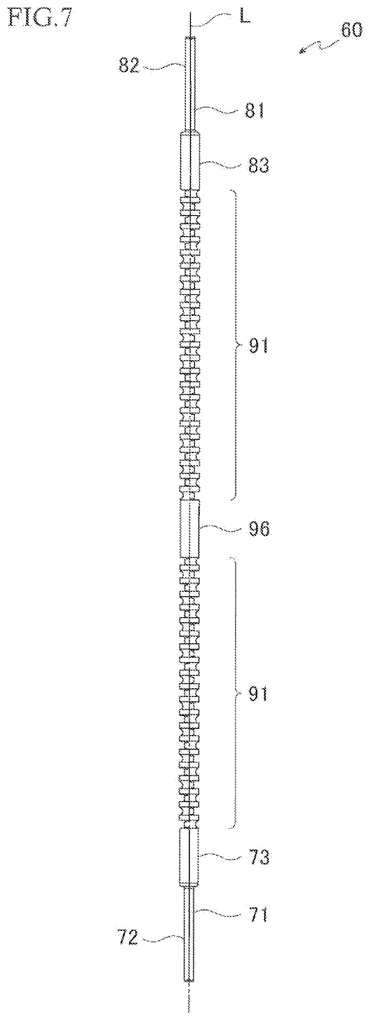

FIGS. 1 to 9 show the first embodiment of the present invention.

An IC socket 10 as a “socket for electric component” according to the embodiment is configured to be disposed on a wiring board 1 as a “first electric component” as shown in FIGS. 1, 4 and 5, accommodate an IC package 2 as a “second electric component” on an upper surface, and come into contact with an electrode (not shown) as a “terminal” of the wiring board 1 and a solder ball (not shown) as a “terminal” of the IC package 2 for electrically connecting those terminals. The IC socket 10 is used as a testing device for the continuity test such as the burn-in testing to the IC package 2, for example.

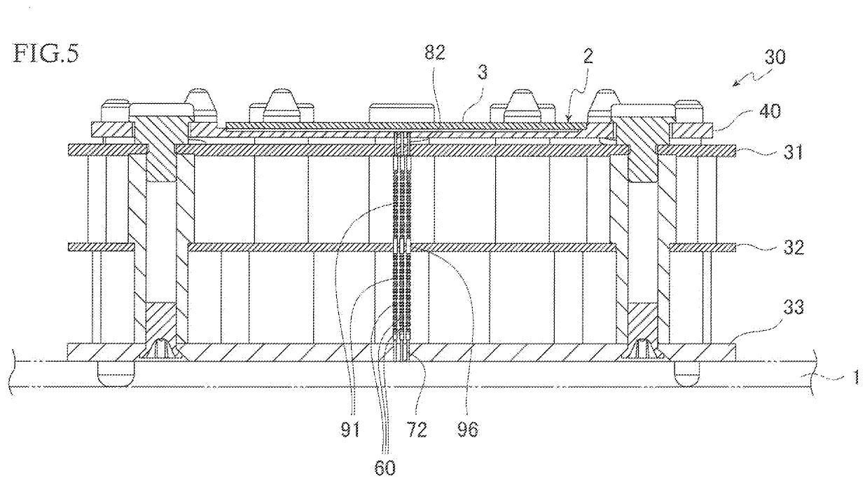

The IC package 2 (see FIG. 5) of the embodiment has a plurality of spherical solder balls arranged in a matrix in a substantially quadrangular prescribed range on a lower surface of a substantially quadrangular package body 3.

As FIG. 1 shows, the IC socket 10 includes a socket body 20 configured to be disposed on the wiring board 1 and accommodate the IC package 2, a pair of cover members (not shown) which rotate with respect to the socket body 20 so as to be opened and closed, and a frame-like operation member (not shown) for rotating operations of the cover members. Detailed explanations of the cover members and the operation member will be omitted.

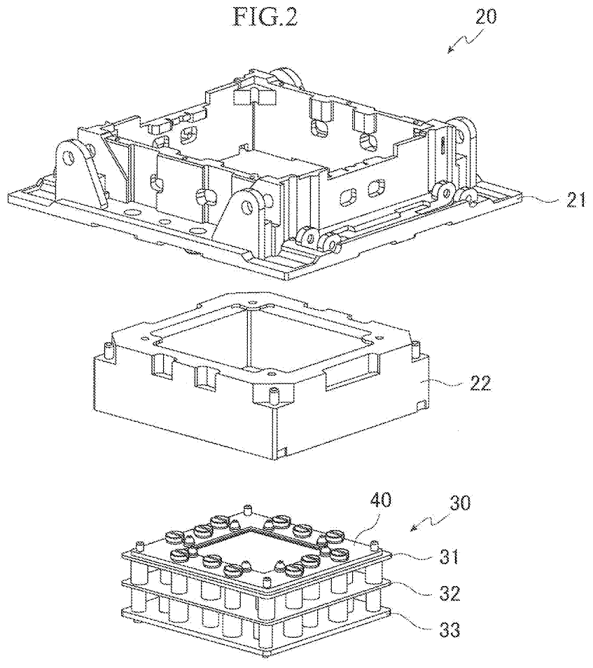

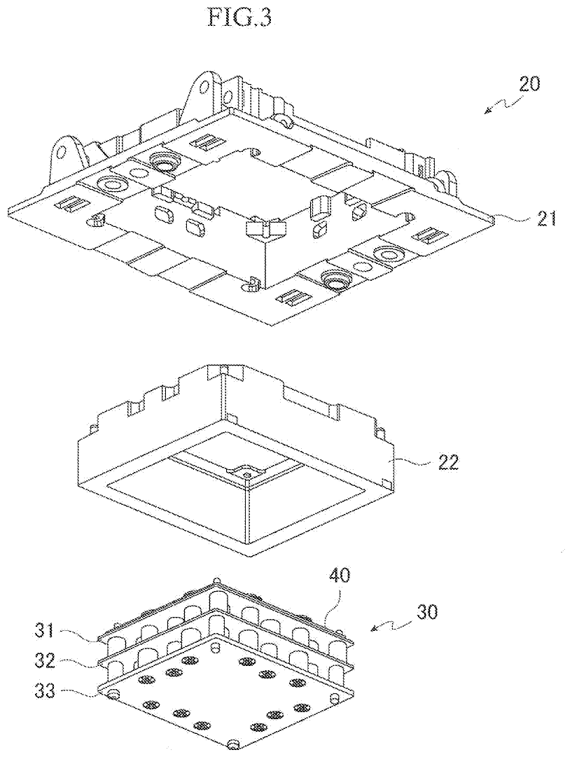

As FIGS. 2 and 3 show, the socket body 20 is formed by disposing a frame member 22 with a quadrangular frame shape in a support member 21 which is formed into a quadrangular frame shape for supporting the cover members and the operation member, and further disposing a contact module 30 in the frame member 22. The contact module 30 has a plurality of contact pins 60 (see FIG. 5 and the like) as “electric contacts” arranged in a matrix, and a floating plate 40 as a “storage part” at the upper surface side for storing the IC package 2.

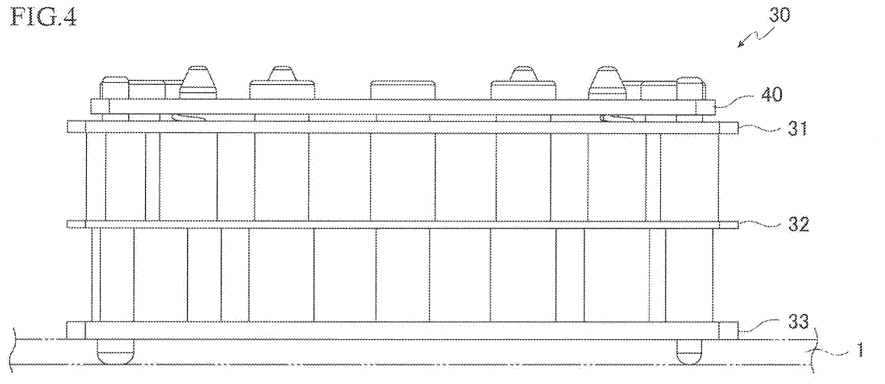

As FIGS. 4 and 5 show, the contact module 30 includes an upper holding member 31, a center holding member 32, a lower holding member 33, the floating plate 40 and the like. The upper holding member 31, the center holding member 32, and the lower holding member 33 are held at predetermined intervals, respectively. The floating plate 40 located above the upper holding member 31 is urged by a spring (not shown) in an upward direction of the socket body 20 so as to be vertically movable with respect to the upper holding member 31, the center holding member 32, and the lower holding member 33 which are held at the predetermined intervals.

The contact pins 60 are inserted into through holes (not shown) which vertically penetrate through the upper holding member 31, the center holding member 32, the lower holding member 33, and the floating plate 40 while being vertically extendable/contractible. In the embodiment, the contact pins 60 are arranged in a matrix with respect to the contact module 30 as described above. However, FIG. 5 conveniently shows only three contact pins 60.

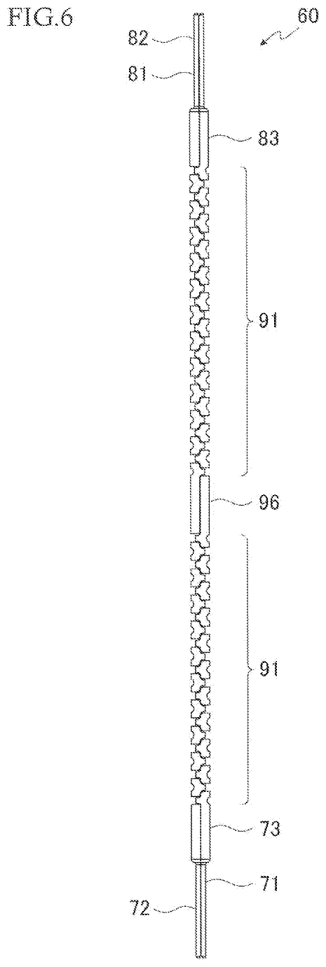

As FIGS. 6 to 8 show, each of the contact pins 60 is constituted by a single conductive member which is formed into a cylindrical shape along an axis L. The contact pin 60 includes a first contact part 71 to be in contact with the electrode of the wiring board 1, a second contact part 81 to be in contact with the solder ball of the IC package 2, and a spring part 91 provided between the first contact part 71 and the second contact part 81. In this embodiment, the contact pin further includes a cylindrical intermediate part 96 which is not in the form of a spring at substantially an intermediate position of the spring part 91 so as to be stably held in the through hole of the center holding member 32. The above-described intermediate part divides the spring part 91 into two sections.

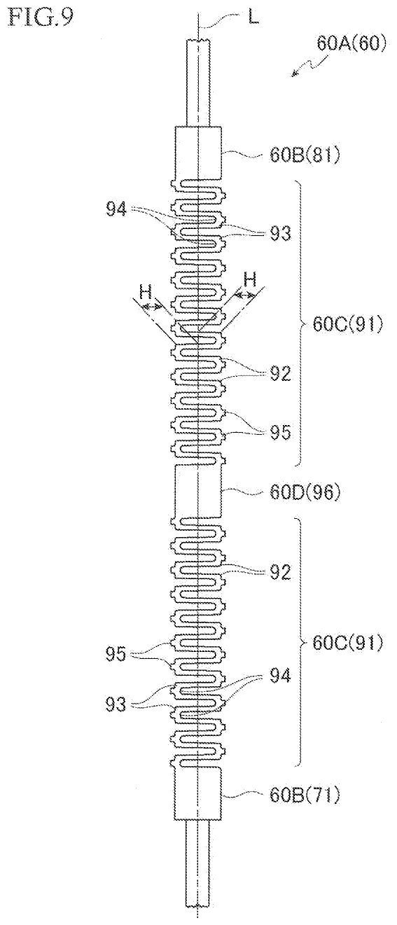

The contact pin 60 is formed from a conductive material 60A as shown in FIG. 9. The conductive material 60A is constituted by a plate-like member having a plate-like part 60B partially provided with a wavy part 60C. In this case, the plate-like parts 60B are formed at both ends. The wavy parts 60C are formed at the center, which are linked to the respective plate-like parts 60B. Another plate-like part 60D is formed at substantially an intermediate position between the wavy parts 60C.

The lower plate-like part 60B as shown in FIG. 9 is curved or bent cylindrically along the axis L in the longitudinal direction from the lower plate-like part 60B to the wavy part 60C so as to form a cylindrical first contact part 71 including a small-diameter first tip end portion 72 to be in contact with the wiring board 1 at the lower side, and a large-diameter part 73 linked to the upper part of the first tip end portion 72.

The upper plate-like part 60B as shown in FIG. 9 is curved or bent cylindrically along the axis L so as to form a cylindrical second contact part 81 including a small-diameter second tip end portion 82 to be in contact with the IC package 2 at the upper side, and a large-diameter part 83 linked to the lower part of the second tip end portion 82.

The wavy part 60C as shown in FIG. 9 is curved or bent cylindrically along the axis L so as to form a cylindrical spring part 91 contiguous with the first contact part 71 and the second contact part 81 while being located therebetween for urging the first contact part 71 and the second contact part 81 in the mutually separating direction along the axis L.

In reference to the developed state as shown in FIG. 9, the spring part 91 includes wave-shaped parts 92 continuously formed while alternately extending from the both sides of the axis L in the longitudinal direction from the first contact part 71 to the second contact part 81 by an equal distance H in the direction orthogonal to the axis L. The cylindrical spring part 91 is constituted by curving or bending those wave-shaped parts semi-cylindrically.

In reference further to FIG. 9, the spring part 91 has outwardly extending projections 93 of the wave-shaped part 92 continuously formed alternately on one and the other sides. The projection 93 of the semi-cylindrical wave-shaped part 92, which extends from the axis L to the one side is configured to confront a recess 94 formed between the projections 93 of the semi-cylindrical wave-shaped part 92 while extending from the axis L to the other side. The projection 93 of the semi-cylindrical wave-shaped part 92, which extends from the axis L to the other side is configured to confront the recess 94 formed between the projections 93 of the semi-cylindrical wave-shaped part 92, projecting from the axis L to the one side. The spring part 91 as shown in FIG. 6 is constituted by forming the above-described alternate structures repeatedly.

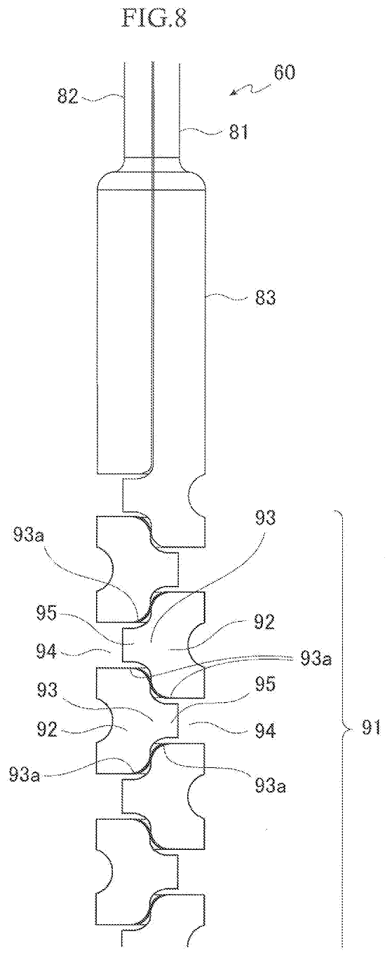

A protrusion 95 extending in the direction orthogonal to the axis L is formed on a tip portion of the projection 93 of each of the wave-shaped parts 92 at the farthest location from the axis L. The protrusion 95 is configured to enter into the confronting recess 94 as shown in FIG. 8.

The another plate-like part 60D is curved or bent cylindrically along the axis L to provide the intermediate part 96 which is not in the form of the spring at substantially the intermediate position of the spring part 91 as shown in FIG. 6.

The thus formed contact pin 60 is configured to have the first contact part 71, the second contact part 81, the intermediate part 96, and two divided spring parts 91.

The thus formed contact pin 60 is configured to have the small-diameter first tip end portion 72 of the first contact part 71 inserted into the through hole of the lower holding member 33 of the contact module 30, and extended downward of the lower holding member 33. The small-diameter second tip end portion 82 of the second contact part 81 is inserted into the through hole of the floating plate 40. The intermediate part 96 of the spring part 91 at substantially an intermediate position is inserted into the through hole of the center holding member 32 of the contact module 30. In this way, the contact pin 60 may be held by the contact module 30.

Functions of the IC socket 10 provided with the contact pins 60 each constituted by the above-described single member will be described.

The IC socket 10 is used in the state where the contact pins 60 are fitted with the contact module 30 of the socket body 20 to allow extension of the first tip end portion 72 of the first contact part 71 downward of the lower holding member 33, and insertion of the second tip end portion 82 of the second contact part 81 into the floating plate 40 as well as insertion of the intermediate part 96 into the center holding member 32.

The IC socket 10 is positioned and fixed to the wiring board 1 so that the first tip end portion 72 of the first contact part 71 is brought into contact with the electrode of the wiring board 1. At this time, the first tip end portion 72 is pushed upward by the wiring board 1 as well as the entire contact pins 60. As a result, the second contact part 81 is also pushed upward.

The IC package 2 is then seated on the floating plate 40 to bring the solder ball into contact with the second tip end portion 82 of the second contact part 81. In the above-described state, the operation member is operated to press the IC package 2 downward using the cover members. The floating plate 40 is lowered together with the IC package 2 against the upward urging force so that the solder ball presses the second tip end portion 82 while being pushed downward against the urging force of the spring part 91.

As the protrusion 95 is configured to enter into the recess 94, when the force is applied in the direction for contracting the spring part 91 along the axis L against the urging force, the protrusion 95 is brought into abutment on side walls 93a of the respective projections 93 at both sides of the recess 94 into which the protrusion 95 has entered by a predetermined contracting amount. The thus applied stopper force prevents further contraction of the spring part 91. As a result, the spring part 91 no longer contracts in excess of the prescribed amount. This makes it possible to prevent failure of plastic deformation of the spring part 91 to the level over the elastically deformable range.

The first contact part 71 and the spring part 91 are integrally linked, and the second contact part 81 and the spring part 91 are integrally linked. As the spring part 91 is compressed, the respective wave-shaped parts 92 of the spring part 91 come into contact with each other. This establishes electric coupling in a short distance from the first contact part 71 to the second contact part 81 compared with the case where electricity flows along the spring part 91 in the developed state as shown in FIG. 9. It is possible to electrically connect the wiring board 1 and the IC package 2 with the low resistance value.

As the spring part 91 is compressed, the abutment state of the protrusion 95 of the spring part 91 on the respective side walls 93a of the projections 93 at both sides of the recess 94 into which the protrusion 95 has entered is held for establishing the electric coupling from the first contact part 71 to the second contact part 81 in the short distance. Further in the state where the electrode of the wiring board 1 is in electric connection to the solder ball of the IC package 2 under the appropriate contact pressure with the spring part 91 which urges the first contact part 71 and the second contact part 81 in the mutually separating direction, the continuity test to the IC package 2, for example, the burn-in testing is conducted.

### Second Embodiment

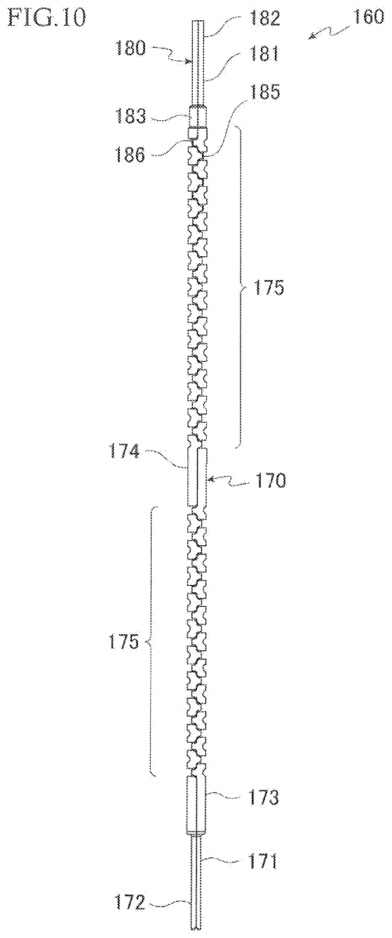

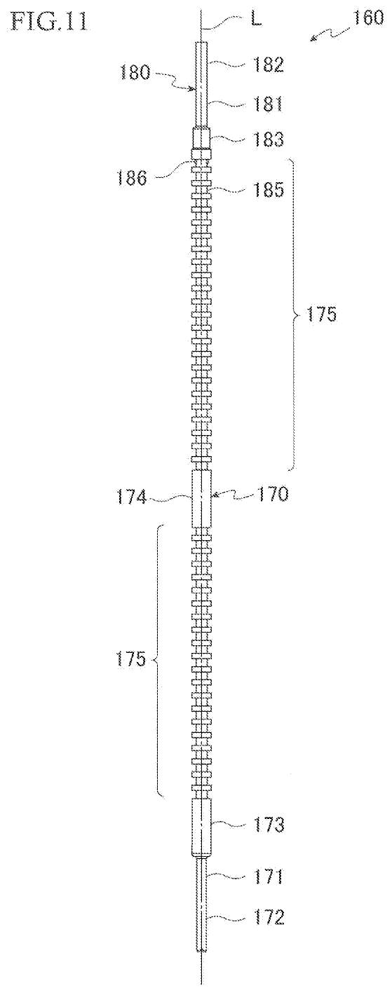

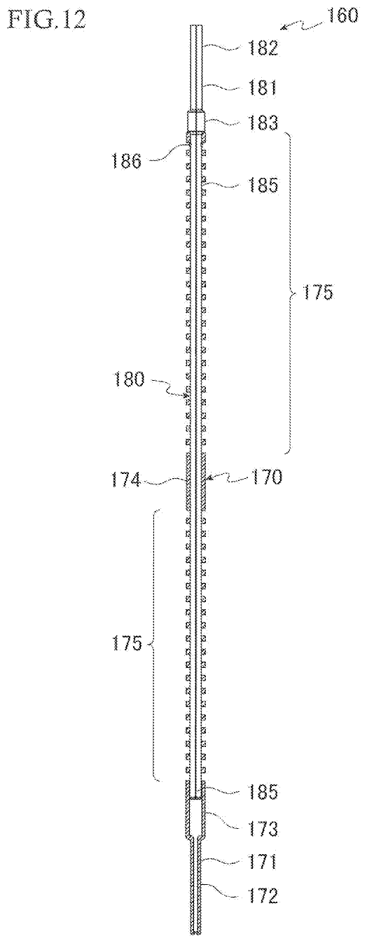

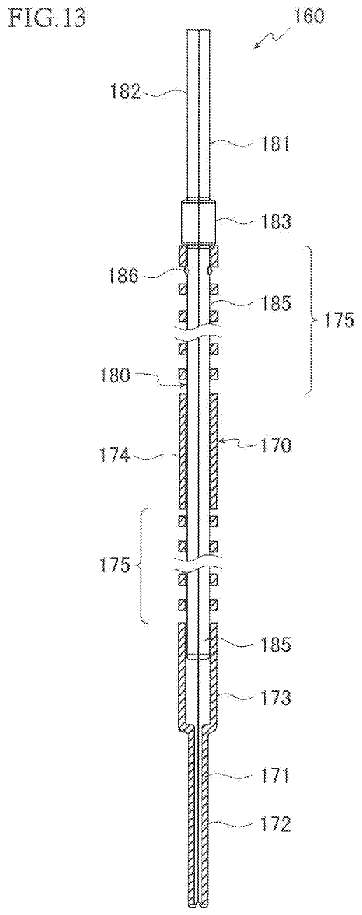

FIGS. 10 to 15 show a second embodiment of the present invention. The embodiment of the present invention is similar to the first embodiment as described above except matters to be described below. Therefore, the matters except those different from the above-described first embodiment will be designated with the same reference signs, and explanations thereof, thus will be omitted.

This embodiment is obtained by modifying the contact pin 60 according to the above-described first embodiment into a contact pin 160 constituted by two members as shown in FIG. 10. The contact pin 160 according to this embodiment will be described hereinafter.

As FIGS. 10 to 14 show, the contact pin 160 of this embodiment includes two members, that is, a first member 170 formed into a conductive cylindrical structure to be in contact with the electrode of the wiring board 1, and a second member 180 formed into a conductive rod-like structure (hollow rod-like shape in this case) to be in contact with the solder ball of the IC package 2.

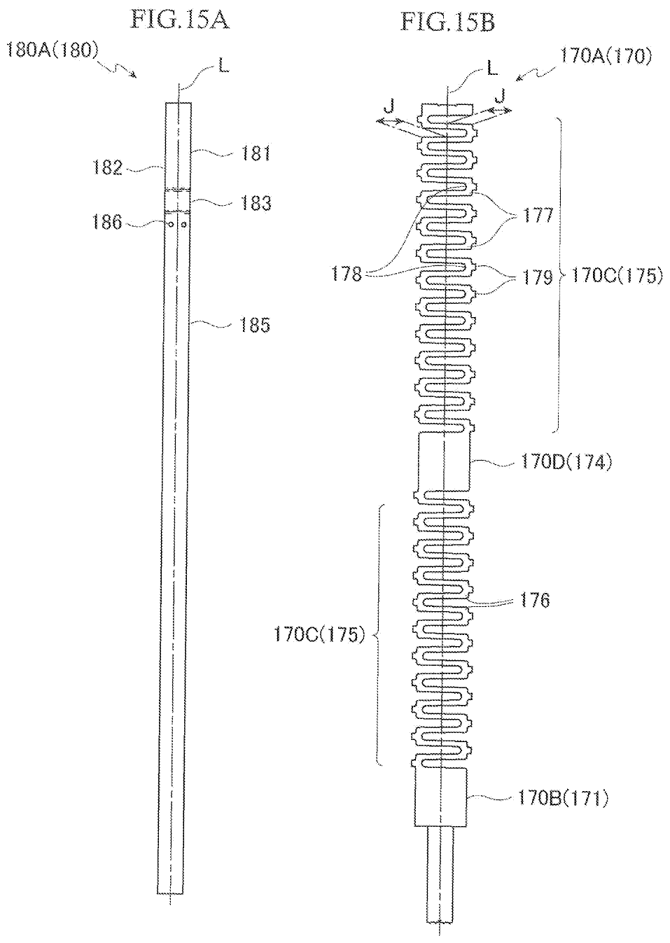

The first member 170 is formed from a first member conductive material 170A as shown in FIG. 15. The first member conductive material 170A is constituted by a plate-like member, having a plate-like part 170B partially provided with a wavy part 170C. In this case, the plate-like part 170B is formed at one end side, and the wavy part 170C is formed at the other end side linked to the plate-like part 170B. Another plate-like part 170D is formed at substantially an intermediate position of the wavy part 170C.

The plate-like part 170B as shown in FIG. 15 is curved or bent cylindrically along the longitudinal axis L from the plate-like part 170B to the wavy part 170C so as to form a cylindrical first contact part 171 which includes a small-diameter first tip end portion 172 to be in contact with the wiring board 1 at the lower side, and a large-diameter inserted portion 173 linked to the upper side of the first tip end portion 172. The inner structure of the inserted portion 173 has a size and a shape which allow slidable insertion of an insertion portion 185 of the second member 180 to be described later.

The wavy part 170C as shown in FIG. 15 is curved or bent cylindrically along the axis L to form a cylindrical spring part 175 which is contiguous with the first contact part 171, and applies urging force to the first contact part 171 and the second contact part 181 in the mutually separating direction along the axis L upon assembly of the contact pin 160 as shown in FIG. 10.

In reference to the developed state as shown in FIG. 15, the spring part 175 includes wave-shaped parts 176 continuously formed while alternately extending from the both sides of the axis L in the longitudinal direction from the first contact part 171 to the spring part 175 by an equal distance J in the direction orthogonal to the axis L. The cylindrical spring part 175 is constituted by curving or bending those wave-shaped parts semi-cylindrically.

In reference further to FIG. 15, the spring part 175 has outwardly extending projections 177 of the wave-shaped part 176 continuously formed alternately on one and the other sides of the axis L. The projection 177 of the semi-cylindrical wave-shaped part 176, which extends from the axis L to the one side is configured to confront a recess 178 formed between the projections 177 of the semi-cylindrical wave-shaped part 176 while extending from the axis L to the other side. The projection 177 of the semi-cylindrical wave-shaped part 176, which extends from the axis L to the other side is configured to confront the recess 178 formed between the projections 177 of the semi-cylindrical wave-shaped part 176, which extends from the axis L to the one side. The spring part 175 as shown in FIG. 10 is constituted by forming the above-described alternate structures repeatedly.

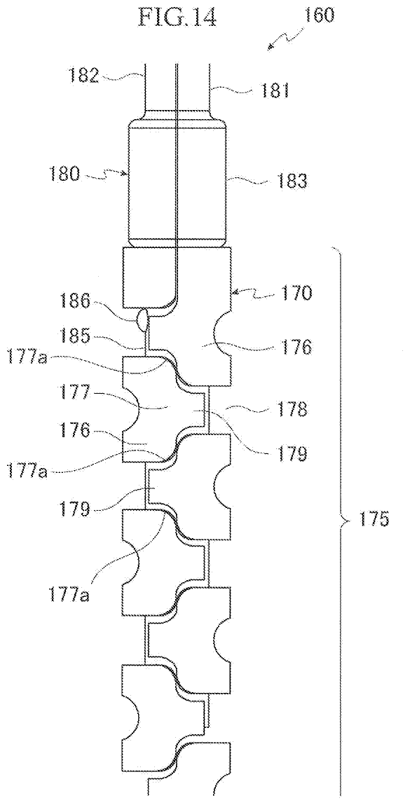

A protrusion 179 extending in the direction orthogonal to the axis L is formed on a tip portion of the projection 177 of each of the wave-shaped parts 176 at the farthest location from the axis L as shown in FIG. 15. The protrusion 179 is configured to enter into the confronting recess 178 as shown in FIG. 14.

The another plate-like part 170D is curved or bent cylindrically along the axis L to provide the intermediate part 174 which is not in the form of the spring at substantially the intermediate position of the spring part 175 as shown in FIG. 10.

The thus formed first member 170 includes the first contact part 171, an intermediate part 174, and two divided spring parts 175.

The second member 180 as a member formed into a rod-like shape along the axis L has a hollow rod-like structure. The second member may be formed to have a solid rod-like structure. The second member 180 is formed from a second member conductive material 180A as shown in FIG. 15. The second member conductive material 180A is formed as a thin and long plate-like member.

The second member conductive material 180A as shown in FIG. 15 is curved or bent cylindrically along the longitudinal axis L, and further curved or bent cylindrically so that only an intermediate portion (the portion to be formed as a lock part 183 of the second contact part 181) has a larger diameter. This may form a cylindrical second contact part 181 having a small-diameter second tip end portion 182 to be in contact with the IC package 2 at the upper side, and a large-diameter lock part 183 linked to the lower side of the second tip end portion 182 as well as a cylindrical insertion portion 185 contiguous with the second contact part 181.

The lock part 183 is formed to have a diameter larger than that of the spring part 175 of the first member 170, on which an end portion of the spring part 175 is brought into abutment.

The insertion portion 185 is configured to have a size and a shape so as to have its diameter smaller than that of the lock part 183 of the second contact part 181, to be inserted to the inside of the spring part 175 of the first member 170, and to be slidably inserted to the inside of the inserted portion 173 of the first contact part 171 of the first member 170. The insertion portion 185 is configured to have a length so as to be inserted to the inside of the inserted portion 173 of the first contact part 171 in the state where no force is applied to the spring part 175 into which the insertion portion has entered in the contracting direction, and configured so as not to have the tip end of the insertion portion 185 reaching a boundary between the inserted portion 173 and the first tip end portion 172 when the stopper force is applied to the spring part 175 under contraction in the contracting direction with the protrusion 179.

A protrusion 186 is formed on a surface of a wall of the insertion portion 185 around the lock part 183 of the second contact part 181 while extending by a predetermined amount. In this case, semi-spherical protrusions 186 are disposed at two opposite points, respectively on the wall surface at the same positions in the direction of the axis L of the insertion portion 185. This makes it possible to hold the spring part 175 in abutment on the lock part 183 so as not to be detached therefrom.

The thus formed second member 180 includes the second contact part 181 and the insertion portion 185.

The contact pin 160 is formed by inserting the insertion portion 185 of the second member 180 into the inserted portion 173 of the spring part 175 and the first contact part 171 of the first member 170, and bringing the end portion of the spring part 175 into abutment on the lock part 183 for holding the spring part 175 with the protrusions 186.

The thus formed contact pin 160 is configured to have the small-diameter first tip end portion 172 of the first contact part 171 of the first member 170 inserted into the through hole of the lower holding member 33 of the contact module 30, and extended downward of the lower holding member 33 (corresponding to the first tip end portion 72 as shown in FIG. 5). The small-diameter second tip end portion 182 of the second contact part 181 of the second member 180 is inserted into the through hole of the floating plate 40 (corresponding to the second tip end portion 82 as shown in FIG. 5). The intermediate part 174 at substantially an intermediate position of the spring part 175 of the first member 170 is inserted into the through hole of the center holding member 32 of the contact module 30 (corresponding to the intermediate part 96 as shown in FIG. 5). In this manner, the contact pin 160 may be held by the contact module 30.

Functions of the IC socket 10 provided with the contact pins 160 each constituted by the first member 170 and the second member 180 as described above will be described.

The IC socket 10 is used in the state where the contact pins 160 are fitted with the contact module 30 of the socket body 20 to allow extension of the first tip end portion 172 of the first contact part 171 of the first member 170 downward of the lower holding member 33, and insertion of the second tip end portion 182 of the second contact part 181 of the second member 180 into the floating plate 40 as well as insertion of the intermediate part 174 of the first member 170 into the center holding member 32.

The IC socket 10 is positioned and fixed to the wiring board 1 so that the first tip end portion 172 of the first contact part 171 is brought into contact with the electrode of the wiring board 1. At this time, the first tip end portion 172 is pushed upward by the wiring board 1 as well as the entire first member 170. As a result, the second member 180 is also pressed upward via the lock part 183 of the second contact part 181 of the second member 180, on which the end portion of the spring part 175 has abutted.

The IC package 2 is then seated on the floating plate 40 to bring the solder ball into contact with the second tip end portion 182 of the second contact part 181. In the above-described state, the operation member is operated to press the IC package 2 downward using the cover members. The floating plate 40 is lowered together with the IC package 2 against the upward urging force so that the solder ball presses the second tip end portion 182 while having the second member 180 being pushed downward against the urging force of the spring part 175.

As the protrusion 179 is configured to enter into the recess 178, when the force is applied in the direction for contracting the spring part 175 along the axis L against the urging force, the protrusion 179 is brought into abutment on side walls 177a of the respective projections 177 at both sides of the recess 178 into which the protrusion 179 has entered by a predetermined contracting amount. The thus applied stopper force prevents further contraction of the spring part 175. As a result, the spring part 175 no longer contracts in excess of the prescribed amount. This makes it possible to prevent failure of plastic deformation of the spring part 175 to the level over the elastically deformable range.

At this time, the insertion portion 185 of the second member 180 is slidably inserted to the inside of the inserted portion 173 of the first contact part 171 of the first member 170 so that the electrode of the wiring board 1 and the solder ball of the IC package 2 are electrically coupled in the short distance via the second contact part 181 and the insertion portion 185 of the second member 180, and the inserted portion 173 and the first contact part 171 of the first member 170. This makes it possible to establish electric connection of those components with the low resistance value.

The spring part 175 integrated with the first contact part 171 has its upper end portion abutted on the second contact part 181. As the spring part 175 is compressed to bring the respective wave-shaped parts 176 of the spring part 175 into abutment on each other, the electric coupling is established from the first contact part 171 to the second contact part 181 in the shorter distance compared with the case where electricity flows along the spring part 175 in the developed state as shown in FIG. 15. Likewise the connection via the insertion portion 185 as described above, it is possible to establish the electric connection between the wiring substrate 1 and the IC package 2 with the low resistance value.

Compression of the spring part 175 allows electric coupling between the first contact part 171 and the second contact part 181 in the short distance through slidable insertion of the insertion portion 185 of the second member 180 to the inside of the inserted portion 173 of the first member 170, and electric coupling from the first contact part 171 to the second contact part 181 in the short distance while holding the abutment state of the protrusion 179 of the spring part 175 on the side walls 177a of the projections 177 at both sides of the recess 178 into which the protrusion 179 has entered. Further in the state where the electrode of the wiring board 1 is electrically connected to the solder ball of the IC package 2 under the appropriate contact pressure with the spring part 175 which urges the first contact part 171 of the first member 170 and the second contact part 181 of the second member 180 in the mutually separating direction, the continuity test to the IC package 2, for example, the burn-in testing is conducted.

The contact pins 60, 160 of the above-described embodiments are configured to allow the projections 93, 177 of the wave-shaped parts 92, 176 on one side to enter into the recesses 94, 178 between the wave-shaped parts 92, 176 on the other side so that the projections 93, 177 on one side are brought into abutment on the projections 93, 177 adjacent to the recesses 94, 178 of the wave-shaped parts 92, 176 on the other side, respectively upon contraction of the spring parts 91, 175 for stopping the contraction movement, and further establishing the conduction state between the projections 93, 177 abutted on each other. It is therefore possible to prevent the plastic deformation of the spring parts 91, 175 in excess of the limit of the elastic deformation. As a result, durability of the contact pins 60, 160 may be improved.

The contact pins 60, 160 of the above-described embodiments are configured to have the protrusions 95, 179 formed on the tip portions of the projections 93, 177, respectively in the direction orthogonal to the axis L. As the protrusions 95, 179 are structured to enter into the recesses 94, 178, the protrusions 95, 179 securely enter into the recesses 94, 178, making it possible to prevent the spring parts 91, 175 from exceeding the limit of the elastic deformation.

The IC sockets 10 according to the above-described embodiments include the above-described contact pins 60, 160, respectively. It is possible to provide the IC socket 10 which prevents the spring parts 91, 175 of the contact pins 60, 160 from plastically deforming in excess of the limit of the elastic deformation.

The first contact pin 60 according to the first embodiment as described above is constituted by the single member. The contact pin 160 according to the second embodiment as described above is constituted by the two members, that is, the first member 170 and the second member 180. Therefore, the number of components used for producing the contact pin 160 may be made smaller than the number of those used for producing the generally employed contact pin constituted by multiple members.

The contact pin 160 according to the second embodiment as described above is configured to allow insertion of the insertion portion 185 of the second member 180 to the inside of the spring part 175 of the first member 170 so as to electrically connect the first member 170 and the second member 180. This makes it possible to reduce an electricity passage distance from the wiring board 1 in contact with the first contact part 171 to the IC package 2 in contact with the second contact part 181 so as to be shorter than the distance of the case where electricity passes through the entire spring part from the first member to reach the second member. As a result, the resistance value of the contact pin 160 may be reduced. The second member 180 serving as the core material may provide the contact pin 160 with higher strength.

The contact pin 160 according to the second embodiment as described above is configured to bring the insertion portion 185 inserted to the inside of the spring part 175 into contact with the first contact part 171. This makes it possible to reduce the electricity passage distance to be shorter than the case where the insertion portion 185 is in contact only with the spring part 175. As a result, the resistance value of the contact pin 160 may be further reduced.

As the IC socket 10 according to the second embodiment as described above includes the above-described contact pin 160, the IC socket 10 allows the number of components used for producing the contact pin 160 to be smaller than the conventional case. As the IC socket 10 includes the above-described contact pin 160, the electricity passage distance from the wiring board 1 in contact with the first contact part 171 to the IC package 2 in contact with second contact part 181 may be made shorter than the conventional case. This makes it possible to provide the IC socket 10 with the reduced resistance value of the contact pin 160.

The “electric contact” according to the present invention is not limited to the contact pins 60, 160 each with the structure according to the corresponding embodiment as described above, but may be applied to the other structure. In the embodiment as described above, the “socket for electric component” according to the present invention has been applied to the IC socket 10 provided with the cover members and the operation member, which is not limited to the one as described above. The socket for electric component may be applied to the IC socket with no cover or the like, and any other device except the IC socket.

### REFERENCE SIGNS LIST

1 wiring board (first electric component)
2 IC package (second electric component)
10 IC socket (socket for electric component)
20 socket body
40 floating plate (storage part)
60, 160 contact pin (electric contact)
60A, 170A conductive material
71, 171 first contact part
81, 181 second contact part
91, 175 spring part
92, 176 wave-shaped part
93, 177 projection
94, 178 recess
95, 179 protrusion
L axis

1. An electric contact to be disposed between a first electric component and a second electric component to establish electric connection therebetween, comprising:
a first contact part to be in contact with the first electric component, a second contact part to be in contact with the second electric component, and a cylindrical spring part formed from a conductive material with a plate-like section and a wavy section, a section between the first contact part and the second contact part being extendable/contractible via the spring part, wherein:
the spring part has a wave-like shape by continuously forming wave-shaped parts alternately on one and the other sides of an axis as a center for connecting the first contact part and the second contact part, and the spring part is formed into a cylindrical shape while having a projection of the wave-shaped part on one side confronting a recess between the projections of the wave-shaped parts on the other side; and
the projection of the wave-shaped part on the one side enters into the recess between the wave-shaped parts on the other side to bring the projection on the one side into abutment on the projection adjacent to the recess of the wave-shaped part on the other side upon contraction of the spring part to stop a contracting motion, and establish a conduction state between the projections abutted on each other.

2. The electric contact according to claim 1, wherein a protrusion is provided on the projection in a direction orthogonal to the axis, and configured to enter into the recess.

3. A socket for electric component comprising:
a socket body which is to be disposed on a first electric component, and includes a storage part to accommodate a second electric component; and
the electric contact according to claim 1, which is disposed in the socket body, and to be in contact with a terminal of the first electric component, and a terminal of the second electric component.

4. A socket for electric component comprising:
a socket body which is to be disposed on a first electric component, and includes a storage part to accommodate a second electric component; and
the electric contact according to claim 2, which is disposed in the socket body, and to be in contact with a terminal of the first electric component, and a terminal of the second electric component.
